(19) United States
(12) Patent Application Publication
(10) Pub. No.: US 2012/0237679 A1
(43) Pub. Date: Sep. 20, 2012

(54) APPARATUS AND METHODS FOR DEPOSITING ONE OR MORE ORGANIC MATERIALS ON A SUBSTRATE

(75) Inventors: Conor F. Madigan, San Francisco, CA (US); Eliyahu Vronsky, Los Altos, CA (US)

(73) Assignee: Kateeva, Inc., Menlo Park, CA (US)

(21) Appl. No.: 13/424,300

(22) Filed: Mar. 19, 2012

Related U.S. Application Data
(60) Provisional application No. 61/453,947, filed on Mar. 17, 2011.

(51) Int. Cl. H01J 9/24; C23C 16/448; F27D 11/00; C23C 16/455

(52) U.S. Cl. 427/248.1; 118/720; 219/428

(57) ABSTRACT

Embodiments are disclosed of apparatus and methods for depositing one or more organic materials onto a substrate. One or more thin films can thereby be formed. The organic materials can be those employed in organic LED (OLED) technologies.

### CROSS-REFERENCE TO RELATED APPLICATION(S)

The instant application claims priority to U.S. Provisional Application No. 61/453,947, filed on Mar. 17, 2011; which is incorporated herein by reference in its entirety.

### FIELD

The present teachings relate to apparatus and methods for depositing one or more organic materials as one or more thin films on a substrate. The organic materials can be those employed in organic LED (OLED) technologies.

### BACKGROUND

There is an on-going desire in the industry to develop new and improved methods and apparatus for depositing thin films of materials on a substrate, such as materials employed in OLED displays.

### SUMMARY

An exemplary and non-limiting summary of various embodiments is set forth next.

Various aspects of the present teachings provide an apparatus for depositing at least one organic material onto a substrate. In various embodiments, the apparatus comprises: a source for directing organic material in substantially collimated vapor form, a substrate material positioned for receiving portions of the organic material, and a pixel mask comprising one or more openings disposed between the source and substrate.

In a variety of embodiments, the source can comprise an evaporation source.

According to various embodiments, the apparatus can further comprise a delivery path extending from the source, through an opening of the pixel mask, and to the substrate.

In various embodiments, the apparatus can be devised at least in part to operate in a relative vacuum. In a variety of embodiments, the apparatus in its entirety can be devised to operate in a relative vacuum.

In a variety of embodiments, the organic material can define a solvent-based composition.

In accordance with various embodiments, the apparatus can include a collimating mask disposed proximate the source. In some embodiments, the collimating mask comprises at least a portion of the source. For example, the source can include a collimating mask disposed along one of its sides, such as the side confronting the substrate.

In various embodiments, the source includes, at least in part, a thermal transfer member including a face defining a plurality of micro-pores or micro-wells, and further including heating elements disposed proximate each of the micro-pores or micro-wells.

Further aspects of the present teachings relate to a method for depositing one or more organic materials onto a substrate. In various embodiments, the method comprises (i) providing an apparatus comprising a source for directing organic material in substantially collimated vapor form; a substrate material positioned for receiving portions of the organic material; and a pixel mask comprising one or more openings disposed between the source and substrate; and, (ii) directing the organic material from the source such that portions of the organic material can pass through openings of the collimation mask in substantially collimated form, while other portions impinge upon a surface of the collimation mask and are thereby blocked from passing onward toward the substrate.

In a variety of embodiments, the apparatus can further comprise a collimating mask disposed proximate the source.

According to various embodiments, at least a portion of step (ii) can be performed in a relative vacuum. In a variety of embodiments, the entirety of step (ii) can be performed in a relative vacuum.

Additional aspects of the present teachings relate to a method for depositing at least one organic material onto a substrate. In various embodiments, the method comprises: (i) providing an apparatus comprising a source for directing organic material in substantially collimated vapor form; a substrate material positioned for receiving portions of the organic material; and a pixel mask comprising one or more openings disposed between the source and substrate; and, (ii) passing portions of substantially collimated organic material emanating from the source through respective openings of the pixel mask, and impinging other portions of the organic material upon a surface of the pixel mask such that the other portions are thereby blocked from passing onward toward the substrate.

In a variety of embodiments, the apparatus can further comprise a collimating mask disposed proximate the source.

In various embodiments, step (ii) can be performed in a relative vacuum.

Additional aspects of the present teachings relate to a device for depositing one or more organic materials onto an OLED display substrate in a desired pattern, comprising: a) a manifold and an OLED display substrate in a chamber at reduced pressure and spaced relative to each other; b) a structure sealingly covering one surface of the manifold, the structure including a plurality of nozzles or openings extending through the structure into the manifold, c) a pixel mask disposed between the substrate and nozzles, wherein the pixel mask defines openings which are spaced from each other and configured in correspondence with the desired pattern of organic material to be deposited onto the OLED display substrate; d) a vapor evaporation apparatus for providing vaporized organic material into the manifold; and e) a system for applying an inert gas under pressure into the manifold so that the inert gas provides a gas flow through each of the nozzles, such gas flow transporting at least portions of the vaporized organic materials from the manifold through the nozzles to provide collimated beams of the inert gas and of the vaporized organic materials and projecting the collimated beams onto the OLED display substrate for depositing the organic materials in the desired pattern on the substrate.

Still further aspects of the present teachings relate to a device for depositing one or more organic materials onto an OLED display substrate in a desired pattern. In various embodiments, the device comprises: a) a chamber at reduced pressure; b) an OLED display substrate disposed in the chamber; c) a collimating mask comprising a plurality of openings extending there through disposed in the chamber, spaced apart from the substrate; d) a pixel mask disposed between the substrate and the collimating mask, wherein the pixel mask defines openings which are spaced from each other and configured in correspondence with the desired pattern of organic material to be deposited onto the substrate; and e) a vapor evaporation source for directing vaporized organic material towards the collimating mask.

In operation, according to various embodiments, vaporized organic materials emanating from the source can pass through the openings of the collimating mask to provide collimated beams of the vaporized organic materials, and the collimated beams can pass through the openings of the pixel mask to be projected onto the substrate for depositing the organic materials in the desired pattern on the substrate.

Further aspects of the present teachings relate to a system, comprising: (i) a thermal transfer member including a plurality of micro-pores or micro-wells defined along one face thereof and one or more heating elements adjacent the perimeter of each micro-pore or micro-well; and (ii) a vacuum containment chamber including a region configured to receive a confronting face portion of the thermal transfer member and also having a retractable door configured to open so that the face of the thermal transfer member can be exposed to a vacuum environment therein.

In various embodiments, the thermal transfer member is disposed adjacent the vacuum containment chamber.

Various aspects of these and other features of various embodiments of the present teachings are included in the following description.

### FIGURES

Various exemplary structures and methods of the present teachings, together with various exemplary objects and advantages thereof, are set forth in the following description taken in conjunction with accompanying drawings, as applicable, in which it will be appreciated that identical reference numerals are employable to identify like or similar elements, and in which:

FIG. 1 is a schematic perspective view depicting an evaporation source for providing organic material in substantially collimated vapor form, a substrate material for receiving portions of the organic material, and a pixel mask disposed between the source and substrate; according to various embodiments of the present teachings.

FIG. 2 is a schematic perspective view depicting an evaporation source for providing organic material at regular intervals along the length of the source; according to various embodiments of the present teachings.

FIG. 3 schematically depicts a collimation mask in side section view, and further shows organic material directed thereto from a source, such as the source shown in FIG. 2, such that a portion of the organic material can pass through an opening of the collimation mask, while another portion impinges upon a surface of the collimation mask and is thereby blocked from passing onward toward a substrate; according to various embodiments of the present teachings.

FIG. 4 is a top plan view, in schematic form, of the collimation mask depicted in FIG. 3.

FIG. 5 is a schematic representation, shown in partial side section, of a substantially planar substrate for receiving an organic material and, adjacent thereto, a pixel mask including a plurality of openings there through, such that portions of an organic material emanating from a collimating source can pass through respective openings of the pixel mask, while other portions impinge upon a surface of the pixel mask and are thereby blocked from passing onward toward the substrate; according to various embodiments of the present teachings.

FIG. 6 is a side-sectional schematic representation of a thermal transfer member, including a plurality of micro-pores or micro-wells defined along one face thereof and one or more heating elements adjacent the perimeter of each micro-pore or micro-well; with the thermal transfer member disposed adjacent a vacuum containment chamber having a region configured to receive a confronting face portion of the thermal transfer member and also having a retractable door configured to open so that the face of the thermal transfer member can be exposed to the vacuum environment therein; in accordance with various embodiments of the present teachings.

### DESCRIPTION OF VARIOUS EMBODIMENTS

Reference will now be made to various embodiments, examples of which are illustrated in the accompanying drawings. While the present teachings will be described in conjunction with various embodiments, it will be understood that they are not intended to limit the present teachings to those embodiments. On the contrary, the present teachings are intended to cover various alternatives, modifications, and equivalents, as will be appreciated by those of skill in the art.

In various embodiments, an apparatus according to the present teachings can include a source for providing an organic material vapor. In some embodiments, for example, the source comprises an evaporative source. In various embodiments, the evaporative source is configured to operate, at least in part, in a vacuum environment. The source can be configured to provide one or more substantially collimated vapor streams. In this regard, in a variety of embodiments, a collimating mask assembly can be employed with the source to effect collimation of the vapor streams. For example, in various embodiments, a collimation mask can be disposed adjacent a source of organic vapor. The collimation mask can comprise a material defining a plurality of openings (e.g., at regular intervals) along its length through which portions of the organic vapor emanating from the source can pass or travel. Such portions that pass through the openings are, thereby, substantially collimated. The substantially collimated vapor streams can be directed towards a substrate. A pixel mask can be interposed between the collimating mask and substrate. The pixel mask can comprise, for example, a material defining a plurality of openings through which portions of the collimated organic material can pass or travel. One or more of the pixel-mask openings can be configured to influence the shape or configuration of organic material to be deposited on the substrate. In operation, portions of the substantially collimated streams of organic material emanating from the collimating source can pass through the openings of the pixel mask and deposit upon the substrate. A film can thereby be formed on the substrate. The film can be of a desired configuration; for example, a striped pattern on the substrate.

Thermal evaporation can be employed, wherein a vapor, or atomic cloud, formed by the evaporation of the coating material in a vacuum environment is carried out in order to form films on the surfaces in the line of sight, as permitted by the collimation mask and pixel mask, between the substrate and the source.

In various embodiments, a thermal evaporator can be employed, for example, comprising an electric resistance heater to melt or sublimate the organic material and raise its vapor pressure to a useful range. This can be done, according to various embodiments, in a containment chamber or box providing a vacuum environment. For example, an apparatus according to the present teachings can include a multiple nozzle thermal evaporation source including a containment box with an evaporation chamber. The containment box with the evaporation chamber can include, for example, a heater and a plurality of effusion nozzles.

In some embodiments, a device for depositing one or more organic materials onto an OLED display substrate can comprise, for example, a) a manifold and an OLED display substrate in a chamber at reduced pressure and spaced relative to each other; b) a structure sealingly covering one surface of the manifold, the structure including a plurality of nozzles, or openings, extending through the structure into the manifold, c) a pixel mask disposed between the substrate and nozzles, wherein the pixel mask defines openings which are spaced from each other, and/or otherwise shaped/configured, in correspondence with the desired pattern of organic material to be deposited onto the OLED display substrate; d) a vapor evaporation apparatus for providing vaporized organic material into the manifold; and e) a system for applying an inert gas under pressure into the manifold so that the inert gas provides a gas flow through each of the nozzles, such gas flow transporting at least portions of the vaporized organic materials from the manifold through the nozzles to provide directed beams of the inert gas and of the vaporized organic materials and projecting the collimated beams onto the OLED display substrate for depositing the organic materials in a desired (e.g., striped) pattern on the substrate.

In various embodiments, an apparatus according to the present teachings can include an inkjet comprising, at least in part, the source of one or more organic materials. For example, one or more inkjets can be configured to eject one or more organic materials onto one or more thermal transfer nozzles, wherein each of the latter can include one or more micro-porous conduits from which the organic material(s) can be ejected to travel or pass along a substantially columnar path. The substantially collimated vapor streams can be directed towards a substrate. A pixel mask can be interposed between the micro-porous conduits and substrate. The micro-porous conduits can comprise, for example, a material defining a plurality of openings through which portions of the collimated organic material can pass, travel, or be ejected. One or more of the micro-porous conduits can be configured to influence the shape or configuration of organic material to be deposited on the substrate. In operation, portions of the substantially collimated streams of organic material emanating from the collimating source can pass through the openings of the pixel mask and deposit upon the substrate. The apparatus can be configured to operate in a vacuum or an environment comprised of an inert gas (e.g., Nitrogen). A film can thereby be formed on the substrate. The film can be of a desired configuration.

In various embodiments, a thermal transfer assembly can be mounted on a movable apparatus, such as a rotatable drum, for receiving organic material(s) and depositing the organic material(s) on one or more substrates. More particularly, in various embodiments, a plurality of such thermal transfer assemblies can be mounted on facets attached to a drum. See, for example, pending US Patent Application No. 2011/0293818, which is incorporated herein by reference in its entirety.

In some embodiments, a collimating source can comprise, at least in part, a plurality of micro-pores, or micro-wells defined along a face of a thermal transfer member. A projection can be located adjacent each micro-pore or micro-well. The projection can, according to some embodiments, fully or partially circumscribe the micro-pores or micro-wells. A heating element can be provided on the distal end of at least a plurality of the projections. In some embodiments a region fully or partially circumscribing each micro-pore or micro-well does not necessarily include a projection structure, but nonetheless is provided with a heating element. A containment chamber or box can be provided, according to various embodiments, so as to provide a vacuum environment therein. In various embodiments, the environment outside of the chamber or box comprises an inert gas (e.g., Nitrogen). A region of the containment chamber or box confronting the thermal transfer member can be provided with an opening or aperture which, in turn, can be fitted with a movable door, valve, or similar closure device. The opening or aperture, in various embodiments, can be dimensioned so as to allow the confronting face of the thermal transfer member to be seated there against, in a sealing fashion. With the face of the thermal transfer in the seated position, and thus in a vacuum environment, the heating elements can be operated so as to heat the face structures, including the micro-pores or micro-wells, and thereby remove residues which can accumulate within the micro-pores or micro-wells during operation in receiving and depositing organic materials. In this way, the thermal transfer member (particularly, the portions that contact organic materials during use) can be cleaned.

Various embodiments contemplate deposition of red R, green G, and blue B organic light emitting films of an organic light emitting display apparatus. In some embodiments, a mask is installed on an organic film deposition crucible installed in a vacuum chamber, and a substrate on which a thin film is to be formed is mounted on or proximate the mask. The mask can then be closely adjacent or adhered to the substrate by, for example, driving a magnet array. In this state, as the organic film deposition crucible operates, an organic material mounted in the organic film deposition crucible can be evaporated to pass through slits of the mask, thereby being deposited on the substrate in a desired or predetermined pattern.

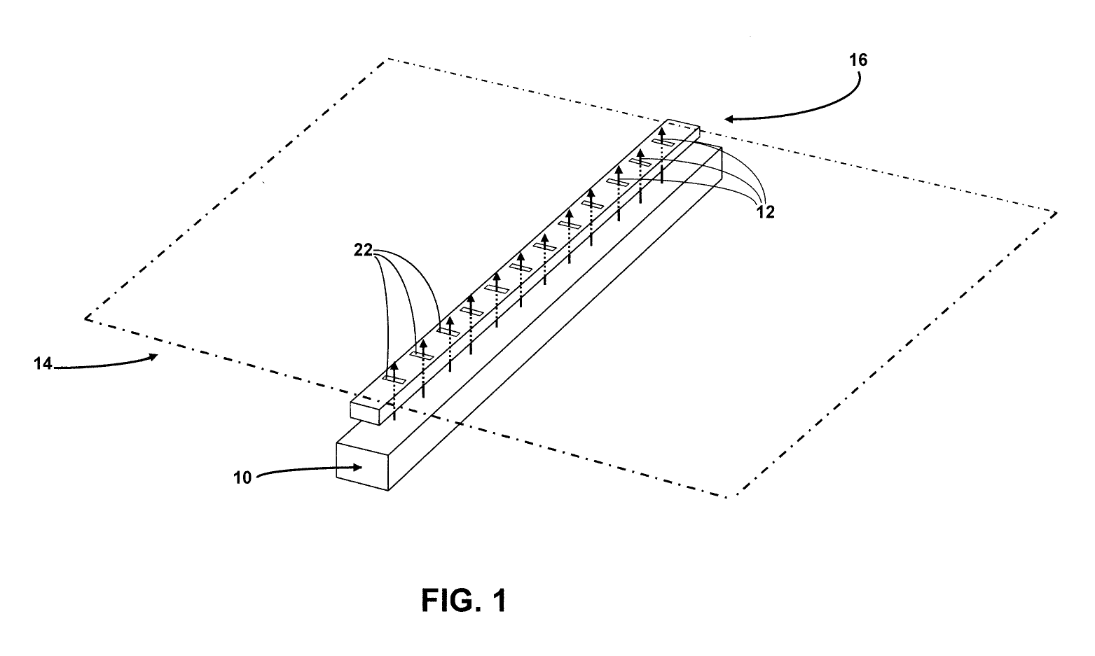

Referring now to the drawings, FIG. 1 is a schematic perspective view depicting an evaporation source 10 for providing organic material 12 in substantially collimated vapor form, a substrate material 14 for receiving portions of the organic material 12, and a pixel mask 16 disposed between the source 10 and substrate 14. In order to apply film material at various locations along the substrate 14, the source and mask assembly can be adapted for movement relative to the substrate 14. In some embodiments, the substrate is moved while the source and mask assembly is maintained stationary.

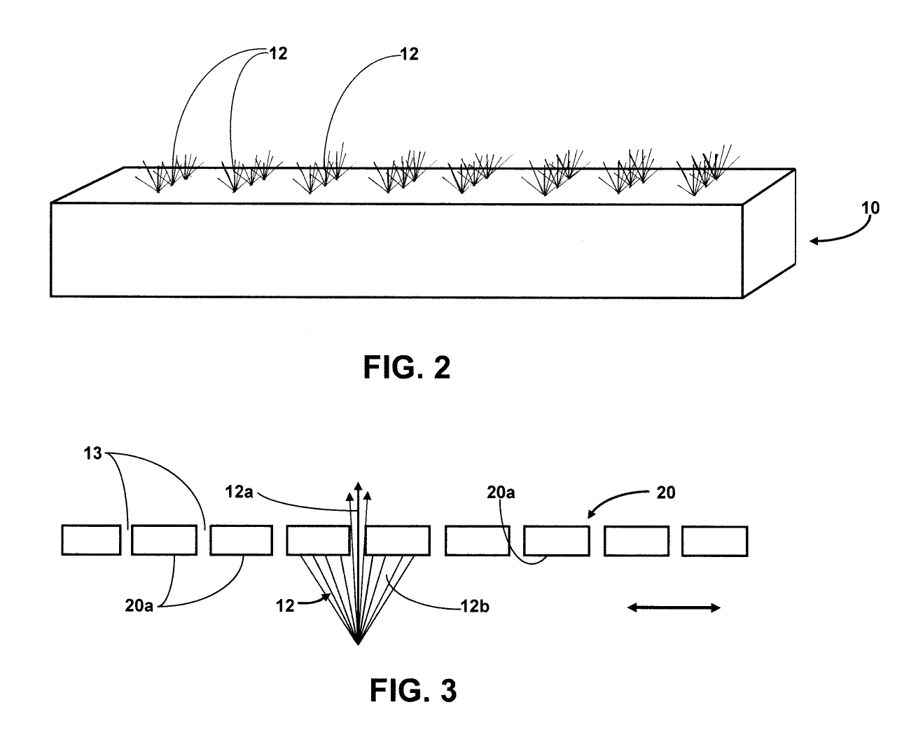

FIG. 2 is a schematic perspective view depicting an evaporation source 10 for providing organic material 12 at regular intervals along the length of the source 10.

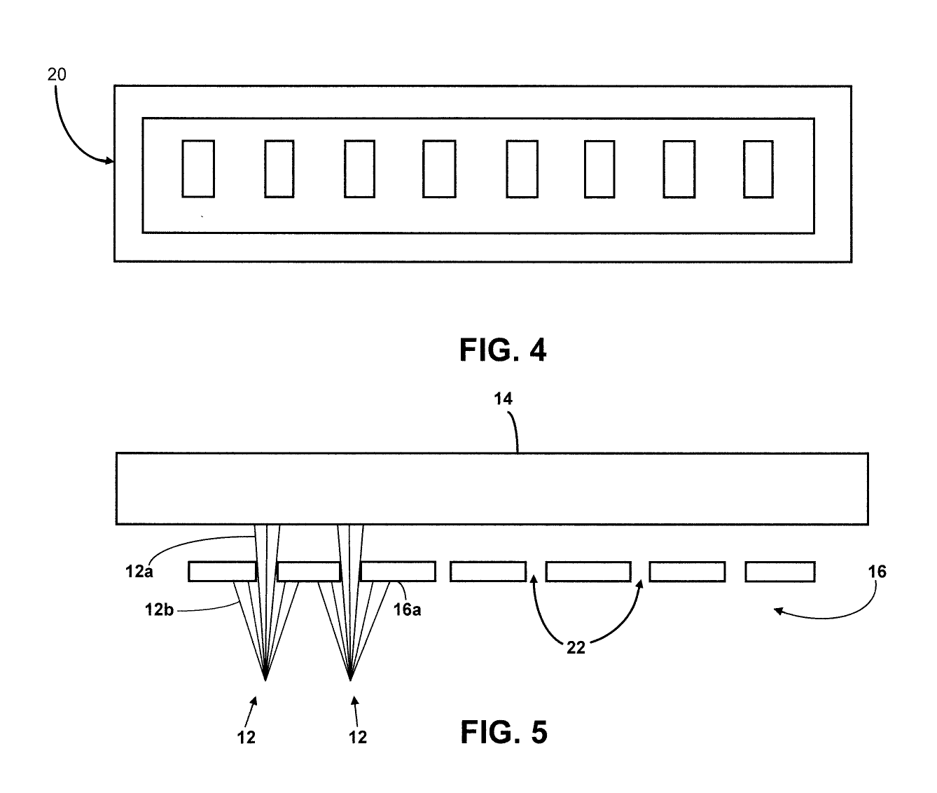

FIGS. 3 and 4 schematically depict views of a collimation mask 20, and further show organic material 12 directed thereto from a source, which can be like or similar to the source 10 shown in FIG. 2, such that a portion 12a of the organic material 12 can pass through an opening 13 of the collimation mask 20, while another portion 12b impinges upon a surface 20a of the collimation mask 20 and is thereby blocked from passing onward toward a substrate.

FIG. 5 is a schematic representation, shown in partial side section, of a substantially planar substrate 14 for receiving an organic material 12 and, adjacent thereto, a pixel mask 16 including a plurality of openings or slits 22, such that portions 12a of an organic material emanating from a collimating source, which can be like or similar to the sources of FIGS. 1 and 2, can pass through respective openings 22 of the pixel mask 16, while other portions 12b impinge upon a surface 16a of the pixel mask 16 and are thereby blocked from passing onward toward the substrate 14.

The distance separating openings 22 of the pixel mask 16 can be, for example, within a range of from about 50 microns to about 200 microns. In some embodiments, the distance is about 100 microns.

In various embodiments, the distance separating the pixel mask 16 and the substrate 14 is within a range of from about 75 microns to about 125 microns. In some embodiments, the distance is about 100 microns.

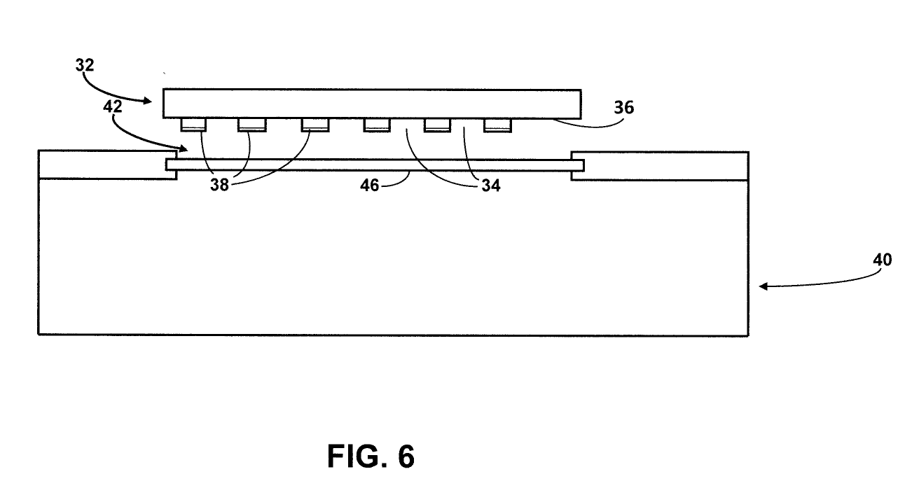

FIG. 6 is a side-sectional schematic representation of a thermal transfer member 32, including a plurality of micro-pores or micro-wells 34 defined along one face 36 thereof and one or more heating elements 38 adjacent the perimeter of each micro-pore or micro-well; with the thermal transfer member 32 disposed adjacent a vacuum containment chamber or box 40 having a region 42 configured to receive a confronting face 36 portion of the thermal transfer member 32 and also having a retractable door or valve 46 configured to open so that the face 36 of the thermal transfer member 32 can be exposed to the vacuum environment therein. The door or valve 46 can otherwise be in the closed position to maintain the vacuum in the containment box or chamber 40 when the confronting face 36 of the thermal transfer member 32 is not in the seated, sealed position.

All references set forth herein are expressly incorporated by reference in their entireties for all purposes.

Those skilled in the art can now appreciate from the foregoing description that the broad teachings herein can be implemented in a variety of forms. Therefore, while the present teachings have been described in connection with various embodiments and examples, the scope of the invention is not intended, and should not be construed to be, limited thereby. Various changes and modifications can be made without departing from the scope of the present teachings.

What is claimed is:

1. An apparatus for depositing at least one organic material onto a substrate, comprising:
a source for directing organic material in substantially collimated vapor form,
a substrate material positioned for receiving portions of the organic material, and
a pixel mask comprising one or more openings disposed between the source and substrate.

2. The apparatus of claim 1, wherein the source comprises an evaporation source.

3. The apparatus of claim 1, further comprising a delivery path extending from the source, through an opening of the pixel mask, and to the substrate.

4. The apparatus of claim 1, devised to operate in a relative vacuum.

5. The apparatus of claim 1, wherein the organic material defines a solvent-based composition.

6. The apparatus of claim 1, including a collimating mask disposed proximate the source.

7. The apparatus of claim 6, wherein said source includes a collimating mask disposed along one of its sides.

8. The apparatus of claim 1, wherein said source includes, at least in part, a thermal transfer member including a face defining a plurality of micro-pores or micro-wells, and further including heating elements disposed proximate each of the micro-pores or micro-wells.

9. A method for depositing an organic material onto a substrate, comprising:
(i) providing an apparatus, comprising a source for directing organic material in substantially collimated vapor form; a substrate material positioned for receiving portions of the organic material; and a pixel mask comprising one or more openings disposed between the source and substrate; and,
(ii) directing the organic material from the source such that portions of the organic material can pass through openings of the collimation mask in substantially collimated form, while other portions impinge upon a surface of the collimation mask and are thereby blocked from passing onward toward the substrate.

10. The method of claim 9, wherein said apparatus further comprises a collimating mask disposed proximate the source.

11. The method of claim 9, wherein step (ii) is performed in a relative vacuum.

12. A method for depositing at least one organic material onto a substrate, comprising:
(i) providing an apparatus, comprising a source for directing organic material in substantially collimated vapor form; a substrate material positioned for receiving portions of the organic material; and a pixel mask comprising one or more openings disposed between the source and substrate; and,
(ii) passing portions of substantially collimated organic material emanating from the source through respective openings of the pixel mask, and impinging other portions of the organic material upon a surface of the pixel mask such that the other portions are thereby blocked from passing onward toward the substrate.

13. The method of claim 12, wherein said apparatus further comprises a collimating mask disposed proximate the source.

14. The method of claim 12, wherein step (ii) is performed in a relative vacuum.

15. A device for depositing one or more organic materials onto an OLED display substrate in a desired pattern, comprising: a) a manifold and an OLED display substrate in a chamber at reduced pressure and spaced relative to each other; b) a structure sealingly covering one surface of the manifold, the structure including a plurality of nozzles or openings extending through the structure into the manifold, c) a pixel mask disposed between the substrate and nozzles, wherein the pixel mask defines openings which are spaced from each other and configured in correspondence with the desired pattern of organic material to be deposited onto the OLED display substrate; d) a vapor evaporation apparatus for providing vaporized organic material into the manifold; and e) a system for applying an inert gas under pressure into the manifold so that the inert gas provides a gas flow through each of the nozzles, such gas flow transporting at least portions of the vaporized organic materials from the manifold through the nozzles to provide collimated beams of the inert gas and of the vaporized organic materials and projecting the collimated beams onto the OLED display substrate for depositing the organic materials in the desired pattern on the substrate.

16. A system, comprising: (i) a thermal transfer member including a plurality of micro-pores or micro-wells defined along one face thereof and one or more heating elements adjacent the perimeter of each micro-pore or micro-well; and (ii) a vacuum containment chamber including a region configured to receive a confronting face portion of the thermal transfer member and also having a retractable door configured to open so that the face of the thermal transfer member can be exposed to a vacuum environment therein.

17. The system of claim 15, wherein the thermal transfer member is disposed adjacent the vacuum containment chamber.

18. The system of claim 15, wherein the thermal transfer member is adapted to move towards and away from the vacuum containment chamber.

19. A device for depositing one or more organic materials onto an OLED display substrate in a desired pattern, comprising:
a) a chamber at reduced pressure;
b) an OLED display substrate disposed in the chamber;
c) a collimating mask comprising a plurality of openings extending there through disposed in the chamber, spaced apart from the substrate,
d) a pixel mask disposed between the substrate and the collimating mask, wherein the pixel mask defines openings which are spaced from each other and configured in correspondence with the desired pattern of organic material to be deposited onto the substrate; and
e) a vapor evaporation source for directing vaporized organic material towards the collimating mask;
wherein at least portions of vaporized organic materials emanating from the source can pass through the openings of the collimating mask to provide collimated beams of the vaporized organic materials, and wherein at least portions of the collimated beams can pass through the openings of the pixel mask to be projected onto the substrate for depositing the organic materials in the desired pattern on the substrate.
